(19) United States
(12) Patent Application Publication
(10) Pub. No.: US 2016/0218014 A1
(43) Pub. Date: Jul. 28, 2016

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Masahiko KUBO, Ibo Hyogo (JP)

(21) Appl. No.: 14/840,880

(22) Filed: Aug. 31, 2015

(30) Foreign Application Priority Data
Jan. 28, 2015 (JP) 2015-014672
Apr. 6, 2015 (JP) 2015-077783

(51) Int. Cl. H01L 21/311; H01L 29/66; H01L 29/423; H01L 29/78

(52) U.S. Cl. CPC H01L 21/31116; H01L 29/7833; H01L 29/66575; H01L 29/4232

(57) ABSTRACT

A semiconductor device includes a semiconductor substrate. A gate insulation film is formed on the semiconductor substrate. A gate electrode is formed on the gate insulation film. A side surface of the upper portion of the gate electrode is inclined downwardly from an upper surface of the gate electrode to a side surface of the lower portion of the gate electrode. A side surface of the lower portion of the gate electrode extends in a direction substantially perpendicular to a surface of the semiconductor substrate.

### CROSS-REFERENCE TO RELATED APPLICATION

This application is based upon and claims the benefit of priority from Japanese Patent Application No. 2015-014672, filed Jan. 28, 2015 and Japanese Patent Application No. 2015-077783, filed Apr. 6, 2015, the entire contents of which are incorporated herein by reference.

### FIELD

Embodiments described herein relate to a semiconductor device and a method of manufacturing the same.

### BACKGROUND

To create a higher performance MISFET (Metal Insulation Semiconductor Field Effect Transistor), a film thickness of a gate insulation film has been progressively reduced. For example, a MISFET has been developed where the film thickness of the gate insulation film is 10 nm or less. To form a gate electrode on such a gate insulation film, the material of the gate electrode is processed anisotropically using an RIE (Reactive Ion Etching) method, for example.

However, in the RIE method, the material of the gate electrode is processed by generating a high electric field of ECR (Electron Cyclotron Resonance) plasma or the like during processing. In such processing, the gate electrode functions as an antenna, and a high electric field is applied to or induced in the gate insulation film between the gate electrode and a substrate. As a result, there may be a case where a tunnel current flows between the gate electrode and the substrate. In such a case, the gate insulation film is damaged or deteriorated. This eventually leads to the occurrence of a defect in an MISFET thus lowering the manufacturing yield and reliability of the MISFET.

Further, when a material of the gate electrode is etched anisotropically using an RIE method, an upper end portion of the gate electrode may be formed into a sheer edge shape at an approximately right angle. Accordingly, in a heating step performed after depositing of an interlayer insulation film on the gate electrode, stress occurs in the interlayer insulation film at the upper end portion of the gate electrode thus giving rise to a possibility that a crack will occur in the interlayer insulation film because of the stress (cracking). Such cracking of the interlayer insulation film lowers the moisture resistance or the like of the interlayer insulation film, and thus of the device.

### DESCRIPTION OF THE DRAWINGS

FIG. 1A and FIG. 1B are cross-sectional views showing one example of the configuration of a MISFET 1 according to an embodiment,

FIG. 2A and FIG. 2B are cross-sectional views showing steps of one example of a method of manufacturing the MISFET 1 according to the embodiment,

FIG. 3A and FIG. 3B are cross-sectional views showing other steps of the example of the method of manufacturing the MISFET 1 which succeed the steps shown in FIG. 2.

### DETAILED DESCRIPTION

According to an embodiment, there are provided a semiconductor device and a method of manufacturing the semiconductor device which can suppress the occurrence of damage to the gate insulation film or then interlayer insulation film, thus improving manufacturing yield and reliability of the devices.

In general, according to one embodiment, a semiconductor device includes a semiconductor substrate, a gate insulation film on the semiconductor substrate, and a gate electrode on the gate insulation film. A side surface of the upper portion of the gate electrode is inclined from an upper surface of the gate electrode to a side surface of the lower portion of the gate electrode. A side surface of the lower portion of the gate electrode extends in a direction substantially perpendicular to a surface of the semiconductor substrate.

Hereinafter, an exemplary embodiment is explained by reference to drawings. The present disclosure is not limited to this embodiment.

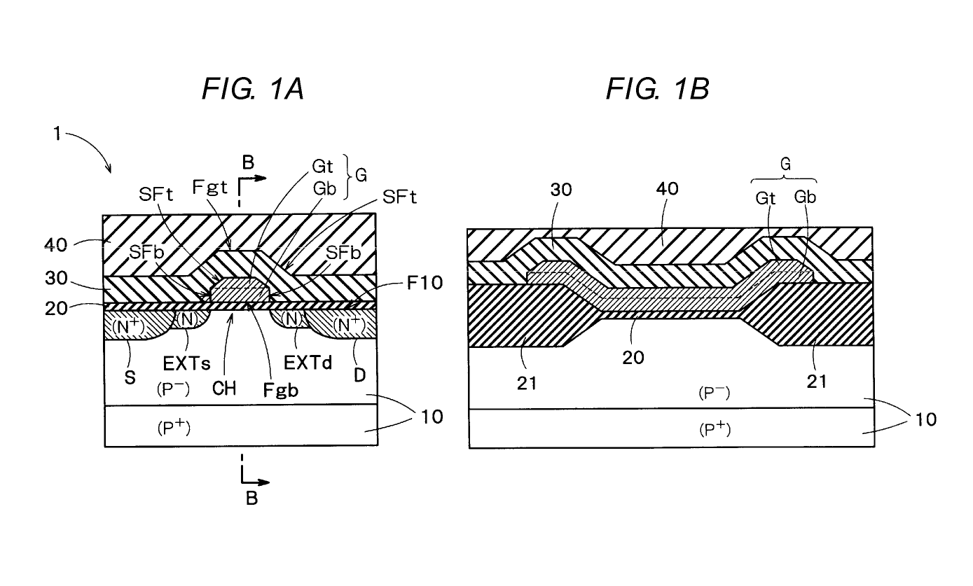

FIG. 1A and FIG. 1B are cross-sectional views showing one example of the configuration of a MISFET 1 according to this embodiment. FIG. 1B is a cross-sectional view taken along a line B-B in FIG. 1A. The MISFET 1 according to this embodiment may be an N-type planar transistor or may be a P-type planar transistor. In the embodiment explained hereinafter, the N-type planar transistor is explained.

The MISFET 1 includes: a semiconductor substrate 10; a gate insulation film 20; interlayer insulation films 30, 40; a gate electrode G; a source layer S; a drain layer D; an extension layer EXTs on a source side; and an extension layer EXTd on a drain side.

The semiconductor substrate 10 is formed of a silicon substrate, for example. In this embodiment, the semiconductor substrate 10 includes a P-type dopant layer (P⁺ layer) of high concentration, and a P-type dopant layer (P⁻ layer) of relatively low concentration formed on the P⁻ layer. The P⁺ layer is a diffusion layer where a concentration of P-type dopant is higher than a concentration of P-type dopant in the P⁻ layer. To form a planar transistor of P type, the semiconductor substrate 10 is configured such that N-type well diffusion layers are formed in place of the P-type dopant layers.

The gate insulation film 20 is formed on the semiconductor substrate 10. The gate insulation film 20 is formed using a silicon oxide film or a material having a higher dielectric constant than the silicon oxide film, for example. Symbol 21 in FIG. 1B indicates an element separation region.

The gate electrode G is formed on the gate insulation film 20. The gate electrode G contains doped polysilicon or a high-melting-point metal material such as molybdenum, tungsten or titanium, for example. Alternatively, the gate electrode G may be made of a compound containing any one of the above-mentioned high-melting-point metal materials (a silicide of any one of these metals, for example). The gate electrode G may be formed of a stacked film having two or more layers made of any one of doped polysilicon, the above-mentioned high-melting-point metal material and a compound of the above-mentioned high-melting-point metal material.

The source layer S is a dopant diffusion layer formed in the semiconductor substrate 10 on one side of the gate electrode G. The drain layer D is a dopant diffusion layer formed in the semiconductor substrate 10 on the other side of the gate electrode G. When the MISFET 1 is an N-type transistor, the source layer S and the drain layer D are respectively formed of a diffusion layer containing an N-type dopant (phosphorus or arsenic, for example). When the MISFET 1 is a P-type transistor, the source layer S and the drain layer D are respectively formed of a diffusion layer containing a P-type dopant (boron, for example).

The interlayer insulation film 30 covers an upper surface and side surfaces of the gate electrode G. The interlayer insulation film 30 is an insulation film such as a silicon oxide film, for example. The interlayer insulation film 40 is formed on the interlayer insulation film 30. In the same manner as the interlayer insulation film 30, the interlayer insulation film 40 is also an insulation film such as a silicon oxide film, for example.

In this embodiment, the gate electrode G includes a lower gate electrode Gb and an upper gate electrode Gt. Side surfaces SFb of the lower gate electrode Gb (that is, lower-portion side surfaces of the gate electrode G) extend in the direction substantially perpendicular to a surface F10 of the semiconductor substrate 10. Side surfaces SFt of the upper gate electrode Gt (that is, upper-portion side surfaces of the gate electrode G) are inclined from the direction substantially perpendicular to the surface F10 of the semiconductor substrate 10. In this embodiment, the upper-portion side surfaces SFt are inclined toward a bottom surface Fgb of the gate electrode G from an upper surface Fgt of the gate electrode G such that the upper-portion side surfaces SFt extend downwardly toward the lower gate electrode Gb as the upper portion side surfaces SFt approach the portion of the lower gate electrode Gb extending substantially perpendicular to the upper surface F10 of the substrate 10, i.e. the side surfaces SFb of the gate electrode G. In other words, the upper-portion side surfaces SFt are forwardly tapered such that the upper-portion side surfaces SFt are inclined to extend in the direction of a lower side (toward the semiconductor substrate 10) from the upper surface Fgt of the gate electrode G in a truncated triangular or extended pyramid form. Due to such a configuration, the area of the upper surface Fgt of the gate electrode G is smaller than the area of the bottom surface Fgb of the gate electrode G. As shown in FIG. 1A and FIG. 1B, the upper-portion side surfaces SFt are downwardly tapered over the whole outer periphery of the upper surface Fgt of the gate electrode G.

As described previously, when the gate electrode G is processed using an RIE method, the gate electrode functions as an antenna so that a tunnel current flows into a gate insulation film 20 disposed between the gate electrode G and the substrate 10. Accordingly, there may be a case where the gate insulation film is damaged.

However, according to this embodiment, as described later, the upper portion Gt of the gate electrode G of the MISFET 1 is isotropically etched using a CDE (Chemical Dry Etching) method, for example, and the lower portion Gb of the gate electrode G of the MISFET 1 is anisotropically etched using an RIE method, for example.

In the CDE method, the material forming the gate electrode G is chemically etched so that the gate electrode G is isotropically processed. Accordingly, the upper portion Gt of the gate electrode G is etched such that the upper-portion side surfaces SFt are downwardly tapered as they approach the sides surfaces SFb of the gate electrode G. That is, the upper portion Gt of the gate electrode G is etched such that the upper-portion side surfaces SFt are inclined from the direction perpendicular to the surface F10 of the semiconductor substrate 10. Damage on the gate insulation film 20 caused by plasma is prevented by using the CDE method. Accordingly, the gate insulation film 20 is not damaged by plasma during processing the upper portion Gt of the gate electrode G.

On the other hand, in the RIE method, the material for forming the gate electrode G is anisotropically etched using plasma. Accordingly, the lower portion Gb of the gate electrode G is etched such that the lower-portion side surfaces SFb extend in a direction substantially perpendicular to the surface F10 of the semiconductor substrate 10. Due to such etching, the gate electrode G of the MISFET 1 having a gate length and a gate width substantially as intended in the device design can be formed, and yet the damage to the device caused by the RIE etching is reduced. In an RIE method, etching is performed using plasma and biasing the substrate on which the devices are formed to directionally etch a material layer on the substrate. In this embodiment, however, the RIE method is used only for processing a portion (lower portion Gb) of the gate electrode G, but is not used for processing the upper portion Gb of the gate electrode G. Accordingly, as compared with the case where the whole material for forming the gate electrode G is processed using an RIE method, in the MISFET 1 according to this embodiment, damage to the gate insulation film 20 as a result of the RIE method is reduced. As a result, according to the MISFET 1 according to this embodiment, manufacturing yield and reliability of resulting devices can be enhanced. For example, when the gate electrode G is made of metal, it is necessary to etch the material for forming the gate electrode G by an RIE method which uses strong plasma, such as high density plasma and/or high bias. In such a case, a charge is likely to be stored or induced in the gate electrode G made of metal. However, by using plasma in processing the lower portion Gb of the gate electrode G while not using plasma in processing the upper portion Gt of the gate electrode G as in the case of this embodiment, damage on the gate insulation film 20 can be suppressed while still forming the gate electrode G having a gate length and a gate width as intended in the device design.

According to this embodiment, the upper-portion side surfaces SFt of the gate electrode G are downwardly tapered. That is, the upper-portion side surfaces SFt of the gate electrode G are inclined in the direction of the bottom surface Fgb of the gate electrode G from the upper surface Fgt of the gate electrode G to the substantially perpendicular to the substrate 10 side portions SFb of the lower portion Gb of the gate electrode G. Accordingly, upper end portions of the upper portion Gt of the gate electrode G are not formed into a sheer edge shape of an approximately right angle, but are formed at an obtuse angle or are rounded. Due to such a configuration, the undulation of the interlayer insulation films 30, 40 which cover the gate electrode G from above is gentle and hence, the interlayer insulation films 30, 40 are less stressed, thereby reducing cracks in the interlayer insulation films 30, 40. Accordingly, the MISFET 1 according to this embodiment can enhance reliability in moisture resistance or the like.

Next, a method of manufacturing the MISFET 1 according to this embodiment is described.

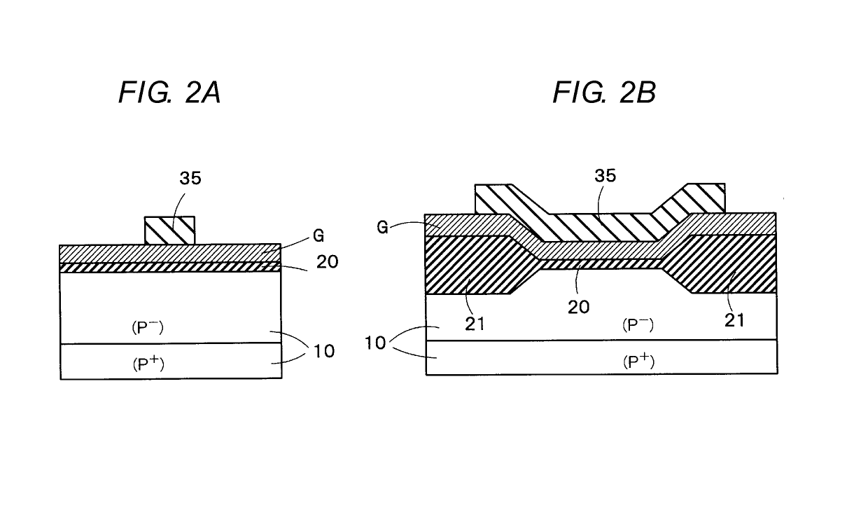

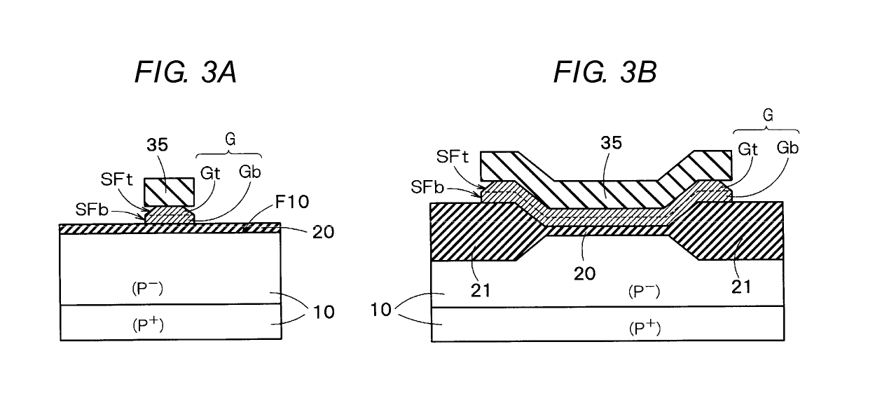

FIG. 2A to FIG. 3B are cross-sectional views showing steps of one example of the method of manufacturing the MISFET 1 according to this embodiment. FIG. 2B is a cross-sectional view taken along a line B-B in FIG. 2A. FIG. 3B is a cross-sectional view taken along a line B-B in FIG. 3A.

Firstly, a gate insulation film 20 is formed on a semiconductor substrate 10. For example, the gate insulation film 20 is a silicon oxide film formed by thermally oxidizing the upper surface of the semiconductor substrate 10. A film thickness of the gate insulation film 20 is approximately 10 nm, for example. Next, a material for forming a gate electrode G is deposited on the gate insulation film 20. As described previously, the material for forming the gate electrode G may be any one of doped polysilicon, the above-mentioned high-melting-point metal material (molybdenum, tungsten, titanium or the like, for example), or a compound of the above-mentioned high-melting-point metal material (a silicide of molybdenum, tungsten, titanium or the like, for example). Alternatively, the gate electrode G may be formed of a stacked film having two or more layers made of any one of doped polysilicon, the above-mentioned high-melting-point metal material, and a compound of the above-mentioned high-melting-point metal material. A film thickness of the material for forming the gate electrode G is approximately 500 nm, for example. Next, a mask member 35 is deposited on the material for forming the gate electrode G. The mask member 35 may be a photoresist mask, or may be a hard mask which is formed of a silicon oxide film, a silicon nitride film or the like. The mask member 35 is formed into a planar pattern in the shape of the gate electrode G by processing. Due to these steps, the structure shown in FIG. 2A and FIG. 2B can be acquired.

Next, a material forming an upper portion Gt of the gate electrode G is isotropically etched using the mask member 35 as a mask (first etching). For example, the upper portion Gt is isotropically etched using a CDE method. Due to such first etching, side surfaces SFt of the upper portion Gt of the gate electrode G are inclined toward a bottom surface Fgb of the gate electrode G from an upper surface Fgt of the gate electrode G to the edge or sides of the electrode G such that the side surfaces SFt extend downwardly in the direction of the sides of the gate electrode G. This inclined or rounded surface SFt undercuts the mask layer 35. That is, the upper-portion side surfaces SFt of the gate electrode G are formed into a downwardly tapered shape. The thickness of the upper portion Gt of the gate electrode G is approximately 300 nm, for example.

The material for forming the gate electrode G is etched to about the halfway point or more of the thickness of the layer forming the electrode G in the etching step using the CDE method and thereafter, the remaining material for forming the gate electrode G (lower portion Gb) is anisotropically etched using an RIE method (second etching) using the same mask as used in the chemical dry etch step. The directionality of ions bombarding the material of the gate electrode G cause the side surface of the gate electrode to be created in alignment with the edge of the mask layer, and a nearly vertical sidewall SFb, nearly perpendicular to or perpendicular to the upper surface F10 of the substrate 10 will be formed. Thus, due to such second etching, side surfaces SFb of the lower portion Gb of the gate electrode G are formed such that the side surfaces SFb extend in a direction substantially perpendicular to a surface F10 of a semiconductor substrate 10. Because only the gate electrode material on the underside of the mask layer adjacent the edge of the mask is removed in the CDE step, the mask material retains the intended shape of the gate electrode. Thus, by such etching step, a gate electrode G having a gate length and a gate width having the dimensions of the intended design can be formed using the mask member 35. A thickness of the lower portion Gb of the gate electrode G is approximately 200 nm, for example.

In this manner, in an initial stage of processing the material for forming the gate electrode G, the gate electrode G is isotropically etched using a CDE method and, thereafter, the gate electrode G is anisotropically etched using an RIE method. After the gate electrode G is etched using an RIE method, in a cross section of the gate electrode G, the upper-portion side surfaces SFt of the gate electrode G are inclined toward the bottom surface of the gate electrode G from the upper surface of the gate electrode G such that the upper-portion side surfaces SFt extend downwardly toward the sides of the gate electrode G. That is, the upper portion Gt of the gate electrode G is downwardly tapered. The lower-portion side surfaces SFb of the gate electrode G extend in the direction substantially perpendicular to the surface F10 of the semiconductor substrate 10. Due to these steps, the structure shown in FIG. 3A and FIG. 3B can be acquired.

Assume the case where a material for forming the gate electrode G is isotropically etched from an upper surface of a gate electrode G to a bottom surface of the gate electrode G using a CDE method. In this case, the whole side surfaces of the gate electrode G are inclined so that the gate electrode G having a gate length and a gate width as intended by the device design cannot be reliably formed. However, in this embodiment, although a material for forming the upper portion Gt of the gate electrode G is isotropically etched using the CDE method, a material for forming the lower portion Gt of the gate electrode G is anisotropically etched using the RIE method. Accordingly, in this embodiment, plasma induced damage caused to the gate insulation film 20 may be significantly suppressed while forming the gate electrode G having a gate length and a gate width as designed. In the CDE method used in this embodiment, an etching gas which reacts with a material for forming the gate electrode G but does not react with the mask member 35 is used.

Next, the mask member 35 is removed and, thereafter, a dopant such as phosphorus or arsenic is implanted into regions where extension layers EXTd, EXTs are to be formed by ion implantation using the gate electrode G as a mask. Then, a dopant such as phosphorus or arsenic is implanted into regions where a source layer S and a drain layer D are to be formed using side wall films (not shown in the drawing) formed on side surfaces of the gate electrode G or a photoresist formed by a photolithography technique as masks. By activating these dopants, the extension layers EXTd, EXTs, the source layer S and the drain layer D shown in FIG. 1A and FIG. 1B are formed. As described previously, the lower-portion side surfaces SFb of the gate electrode G extend in the direction substantially perpendicular to the surface F10 of the semiconductor substrate 10 so that the gate electrode G having a gate length and a gate width as designed is formed over the underlying channel region of the substrate 10. Accordingly, a distance (channel length) between the extension layer EXTd and the extension layer EXTs, and a width of the extension layers EXTd and EXTs in the direction perpendicular to the channel length direction (channel width) may be also set as designed.

Next, as shown in FIG. 1A and FIG. 1B, an interlayer insulation film 30 is formed so as to cover the upper surface, the upper-portion side surfaces SFt and the lower-portion side surfaces SFb of the gate electrode G. Then, the interlayer insulation film 40 is deposited on the interlayer insulation film 30. Thereafter, by forming a contact, a wiring layer and the like, a MISFET 1 according to this embodiment is completed.

According to this embodiment, in an initial stage of processing a material for forming the gate electrode G, the gate electrode G is isotropically etched using a CDE method. As described previously, damage caused on the gate insulation film 20 by plasma is reduced in the CDE method. Accordingly, although the upper portion Gt of the gate electrode G is etched such that the upper-portion side surfaces SFt have a downwardly tapered shape, the gate insulation film 20 is minimally damaged by plasma during processing the upper portion Gt of the gate electrode G.

On the other hand, from about the halfway point of etch processing the material for forming the gate electrode G, the gate electrode G is anisotropically etched using the RIE method. As described previously, etching is performed using plasma in an RIE method. However, in this embodiment, the RIE method which performs etching using plasma is used only for processing a portion (lower portion Gb) of the gate electrode G. Accordingly, the time is shortened during which the material for forming the gate electrode G is exposed to a plasma environment. As a result, in the MISFET 1 according to this embodiment, damage which the gate insulation film 20 receives by plasma in an RIE method is small. In this manner, the MISFET 1 according to this embodiment may have enhanced manufacturing yield and reliability. For example, when the gate electrode G is made of metal, it is necessary to etch the material for forming the gate electrode G using an RIE method which uses strong plasma, such as high density plasma and/or high bias. In this case, a charge is likely to be stored or induced in the gate electrode G made of metal so that the gate electrode G is likely to become charged up. In this embodiment, however, etching by an RIE method is performed for processing only the lower portion Gb of the gate electrode G, but is not performed for processing the upper portion Gt of the gate electrode G. As a result, according to this embodiment, damage on the gate insulation film 20 caused by plasma may is suppressed.

According to this embodiment, the lower portion Gb of the gate electrode G is anisotropically etched using an RIE method and hence, the gate electrode G having a gate length and a gate width as designed may be formed, and the MISFET 1 having a channel length and a channel width as designed may be formed.

Further, according to this embodiment, upper end portions of the upper portion Gt of the gate electrode G are not formed into a sheer edge shape of a substantially right angle, but are formed at an obtuse angle or are rounded. Due to such a configuration, the interlayer insulation film 30 which covers the gate electrode G from above is less stressed and hence, the interlayer insulation film 30 exhibits a high resistance against stress. As a result, the MISFET 1 according to this embodiment may have enhanced reliability in moisture resistance or the like.

For example, assume that the MISFET 1 includes a MoSi having a thickness of approximately 500 nm as a gate electrode G (gate length: 700 nm), and a gate oxide film having a thickness of approximately 10 nm as a gate insulation film 20. When a material for forming the gate electrode G is processed from an upper surface of the gate electrode G to a bottom surface of the gate electrode G using an RIE method, the leakage defect rate between a gate and a source of the MISFET 1 is 5%. In contrast, when a material for forming the gate electrode G is processed using both a CDE method and an RIE method as in the case of this embodiment, the leakage defect rate between a gate and a source of the MISFET 1 is 0.5%.

Further, coverage of the interlayer insulation film 30 on the surface of the gate electrode G and gate insulating film 10 is improved and hence, in the MISFET 1 according to this embodiment, a change rate of leak current may be reduced by approximately 10% in a reliability test such as a moisture resistance acceleration PCT (Pressure Cooker Test). For example, according to this embodiment, reduction in leak current during such a reliability test, referring to the difference in leak current before the test and after the test, is approximately 10% less. In this manner, according to this embodiment, the reliability of the MISFET 1 may be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a gate insulation film on the semiconductor substrate; and
a gate electrode on the gate insulation film, wherein
a side surface of an upper portion of the gate electrode is inclined downwardly from an upper surface of the gate electrode to a side surface of a lower portion of the gate electrode, and
a side surface of the lower portion of the gate electrode extends in a direction substantially perpendicular to a surface of the semiconductor substrate.

2. The semiconductor device according to claim 1, wherein the upper-portion side surface of the gate electrode is inclined in a downwardly tapered shape.

3. The semiconductor device according to claim 1, further comprising:
an interlayer insulation film covering an upper surface, the upper-portion side surface, and the lower-portion side surface of the gate electrode.

4. The semiconductor device according to claim 1, wherein the gate electrode comprises polysilicon.

5. The semiconductor device according to claim 1, wherein the gate electrode comprises a high-melting-point metal material comprising at least one of molybdenum, tungsten, and titanium, or a compound containing any one thereof.

6. The semiconductor device according to claim 5, wherein the high-melting-point metal material comprises a silicide of at least one of molybdenum, tungsten, and titanium.

7. The semiconductor device according to claim 1, wherein the upper-portion side surface of the gate electrode is rounded.

8. The semiconductor device according to claim 1, further comprising:
a source extension provided in the substrate to one side of the gate electrode; and
a drain extension provided in the substrate on an opposite side of the gate electrode.

9. A method of manufacturing a semiconductor device comprising:
forming a gate insulation film on a semiconductor substrate;
forming a material for forming a gate electrode on the gate insulation film;
performing first etching of the material for forming a gate electrode by isotropically etching an upper portion of the material for forming the gate electrode; and
performing second etching of the material for forming a gate electrode by anisotropically etching a lower portion of the material for forming the gate electrode.

10. The method of claim 9, wherein
the first etching is performed using a chemical dry etching method, and
the second etching is performed using a reactive ion etching method.

11. The method of claim 9, wherein
after performing the second etching, an upper-portion side surface of the gate electrode is inclined in the direction of the bottom surface of the gate electrode from an upper surface of the gate electrode to the location of the upper surface adjacent the side of the gate electrode.

12. The method of claim 9, further comprising:
forming a drain region in the substrate in a location spaced from a first side of the gate electrode; and
forming a source region in the substrate in a location spaced from a second side of the gate electrode, the second side of the gate electrode located opposite to the first side of the gate electrode.

13. The method of claim 12, further comprising:
forming a drain extension region in the substrate between the first side of the gate electrode and the drain region; and
forming a source extension region in the substrate between the source region and the second side of the gate electrode.

14. The method of claim 13, wherein the source and drain regions extend further inwardly of the surface of the substrate than the source extension and the drain extension.

15. The method of claim 9, wherein the material for forming the gate electrode comprises at least one of molybdenum, tungsten, and titanium, or a compound containing any one thereof.

16. A semiconductor device, comprising:
a substrate comprising a source region, a drain region, and a channel region between the drain region and the source region; and
a gate electrode provided over the upper surface of the substrate and overlying the channel region of the substrate and located thereon between the source region and the drain region, the gate electrode including:
a first portion adjacent to the upper surface of the substrate having a side wall extending substantially perpendicular to the upper surface of the substrate; and
a second portion disposed over the first portion, the second portion having sidewalls extending downwardly and laterally from an upper surface thereof to a location adjacent to the side of the first portion.

17. The semiconductor device of claim 16, wherein the first portion of the electrode and the second portion of the electrode are one continuous material layer.

18. The semiconductor device of claim 16, wherein the first portion of the electrode and the second portion of the electrode comprise different materials.

19. The semiconductor device of claim 16, wherein the sidewalls of the second portion are rounded.

20. The semiconductor device of claim 16, wherein the sidewalls of the second portion form a taper from the upper surface of the second portion to the side of the first portion.
